(19) United States
(12) Patent Application Publication
(10) Pub. No.: US 2013/0146114 A1
(43) Pub. Date: Jun. 13, 2013

(54) THERMOELECTRIC ELEMENT

(71) Applicant: Moon Gyu JANG, Daejeon (KR)

(72) Inventor: Moon Gyu JANG, Daejeon (KR)

(73) Assignee: ELECTRONICS AND TELECOMMUNICATIONS RESEARCH INSTITUTE, Daejeon (KR)

(21) Appl. No.: 13/610,981

(22) Filed: Sep. 12, 2012

(30) Foreign Application Priority Data
Dec. 12, 2011 (KR) 10-2011-0132563

(51) Int. Cl. H01L 35/28

(52) U.S. Cl. 136/200

(57) ABSTRACT

Disclosed is a thermoelectric element capable of being easily fabricated by employing a semiconductor CMOS process, and improving the thermoelectric efficiency by reducing thermal conductivity while improving electric conductivity between a heat absorption part and a heat emission unit. The thermoelectric element according to an exemplary embodiment of the present disclosure includes a common electrode configured to absorb heat; a first electrode and a second electrode formed on an identical plane to a plane of the common electrode and configured to emit heat; an N-leg connected between the common electrode and the first electrode and configured to supply electrons; and a P-leg connected between the common electrode and the second electrode and configured to supply holes, in which a barrier material for suppressing thermal conduction between the common electrode and the first and second electrodes is formed in the N-leg and the P-leg.

### CROSS-REFERENCE TO RELATED APPLICATIONS

This application is based on and claims priority from Korean Patent Application No. 10-2011-0132563, filed on Dec. 12, 2011, with the Korean Intellectual Property Office, the disclosure of which is incorporated herein in its entirety by reference.

### TECHNICAL FIELD

The present disclosure relates to a thermoelectric element fabricated using a semiconductor material.

### BACKGROUND

A thermoelectric element is an element converting thermal energy into electric energy or causing a temperature difference by applying electric energy. According to the recent increase in interests of clean energy, many researches on the thermoelectric element have been conducted.

For an index for estimating thermoelectric efficiency of the thermoelectric element, a ZT (thermoelectric figure of merit) value is used. The ZT value is in proportionate to electric conductivity and the square of the Seebeck coefficient, and is inversely proportionate to thermal conductivity. Those characteristics significantly depend on an inherent property of a material. In case of a metal, the Seebeck coefficient is very low in terms of several uV/K, and electric conductivity is proportionate to thermal conductivity according to the Wiedemann-Franz law. This means that in the metal, the heat is generally transferred by free charge through electrons or holes. Accordingly, in a case of the metal, it is difficult to implement low thermal conductivity essentially required in the thermoelectric element, and thus the improvement of the ZT value by using the metal is actually impossible. However, since a charge concentration may be freely adjusted in a semiconductor, the thermal transfer by the free charge may be appropriately controlled. Accordingly, in a case of the semiconductor, a main medium factor for the heat transfer is a lattice, and quantum description of a lattice-type vibration by waves is phonon. Accordingly, if the heat transfer is minimized and the propagation of the phonon is suppressed by appropriately adjusting the concentration of the free charge in the semiconductor, the thermal conductivity may be sharply decreased.

In the meantime, for a commercialized material for the thermoelectric element, Bi₂Te₃ has been applied around an ordinary temperature and an intermediate temperature and SiGe has been applied at a high temperature. A ZT value of Bi₂Te₃ is 0.7 at an ordinary temperature, and has a maximum value of 0.9 at 120° C. A ZT value of SiGe is approximately 0.1 at an ordinary temperature, and has a maximum value of 0.9 at 900° C. (see the MRS BULLETIN, Vol. 31, 2006, p. 188).

Recently, research on the thermoelectric element based on silicon that is a basic material in a semiconductor industry has received attention. Since the silicon has very high thermal conductivity of 150 W/m·K, a ZT value is 0.01, it was considered that the silicon was difficult to be utilized as the thermoelectric element. However, it is recently reported that the thermal conductivity of a silicon nanowire grown through a chemical vapor deposition (CVD) may be reduced up to 0.01 times or lower, and thus the ZT value approximates to 1 (see the Nature, Vol. 451, 2008, p. 163).

### SUMMARY

The present disclosure has been made in an effort to provide a thermoelectric element capable of being easily fabricated by employing a semiconductor CMOS process, and improving thermoelectric efficiency by reducing thermal conductivity while increasing electric conductivity between a heat absorption part and a heat emission part.

An exemplary embodiment of the present disclosure provides a thermoelectric element including: a common electrode configured to absorb heat; a first electrode and a second electrode formed on an identical plane to a plane of the common electrode and configured to emit heat; an N-leg connected between the common electrode and the first electrode and configured to supply electrons; and a P-leg connected between the common electrode and the second electrode and configured to supply holes, in which a barrier material for suppressing thermal conduction between the common electrode and the first and second electrodes is formed in the N-leg and the P-leg.

The barrier material may have electric conductivity equal to or larger and thermal conductivity smaller than that of a semiconductor material constituting the N-leg and the P-leg.

The barrier material may be formed of a metal-semiconductor compound including at least one of erbium (Er), europium (Eu), samarium (Sm), magnesium (Mg), platinum (Pt), ytterbium (Yb), nickel (Ni), cobalt (Co) and titanium (Ti) for preventing propagation of phonon.

According to the exemplary embodiment of the present disclosure, the semiconductor material and the barrier region material are formed within the regions of the legs (N-leg and P-leg) connecting the high temperature part (common electrode) and the low temperature part (first and second electrodes) of the thermoelectric element, thereby improving the electric conductivity and reducing the thermal conductivity within the legs. Accordingly, it is possible to improve the thermoelectric efficiency of the thermoelectric element.

Further, the semiconductor material based on silicon (Si), germanium (Ge) and graphene is used as a thermoelectric material, thereby fabricating the thermoelectric element by easily employing the semiconductor CMOS process.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating a configuration of a thermoelectric element according to an exemplary embodiment of the present disclosure.

FIGS. 2, 3 and 4 are diagrams illustrating a form of a barrier material according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

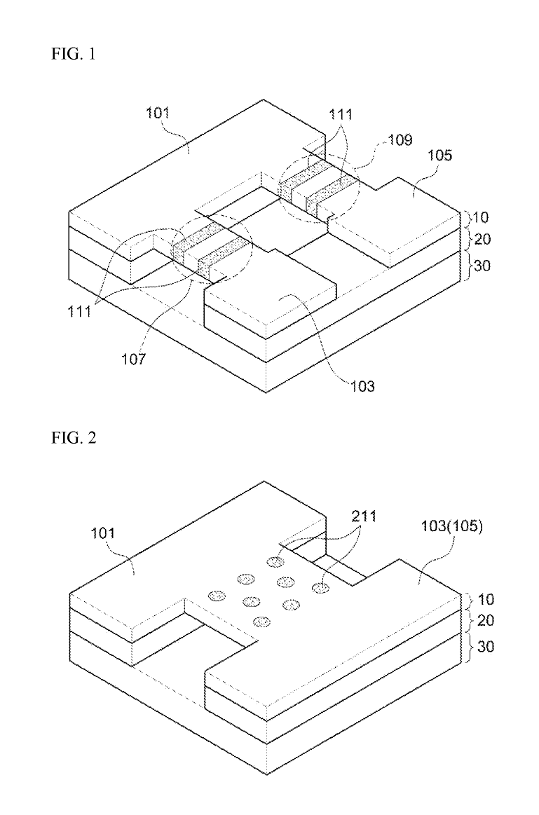

FIG. 1 is a diagram illustrating a configuration of a thermoelectric element according to an exemplary embodiment of the present disclosure.

Referring to FIG. 1, the thermoelectric element according to the exemplary embodiment of the present disclosure includes a common electrode 101 configured to absorb heat, a first electrode 103 and a second electrode 105 formed on the same plane as that of the common electrode 101 and configured to emit heat, an N-leg 107 connected between the common electrode 101 and the first electrode 103 and configured to supply electrons and a P-leg 109 connected between the common electrode 101 and the second electrode 105 and configured to supply holes. A barrier material 111 for suppressing thermal conduction between the common electrode 101 and the first and second electrodes 103 and 105 is formed in the N-leg 107 and the P-leg 109.

The first and second legs 107 and 109 function to transfer heat absorbed by the common electrode 101 to the first and second electrodes 103 and 105. Here, in order to maximize thermoelectric efficiency of the thermoelectric element, the common electrode 101 is required to maximally absorb the heat and to transfer all of the absorbed heat to the N-leg 107 and the P-leg 109. The N-leg 107 and the P-leg 109 are required to transfer the heat received from the common electrode 101 to the first and second electrodes 103 and 105 as slowly as possible. The first and second electrodes 103 and 105 are required to emit the heat transferred from the N-leg 107 and the P-leg 109 as much as possible. That is, a sufficient temperature difference is required to be secured between the common electrode 101 and the first and second electrodes 103 and 105.

To this end, the barrier material 111 within the N-leg 107 and the P-leg 109 needs to be formed of a material having electric conductivity equal to or larger and thermal conductivity smaller than that of a semiconductor material constituting the N-leg 107 and the P-leg 109. The barrier material 111 and the semiconductor material may be ohmic-contacted to each other.

The barrier material 111 may be formed of a metal-semiconductor compound for suppressing phonon that is a medium for thermal transfer. The metal material may include at least one of erbium (Er), europium (Eu), samarium (Sm), magnesium (Mg), platinum (Pt), ytterbium (Yb), nickel (Ni), cobalt (Co) and titanium (Ti). When the materials are heat treated in a state of being in contact with silicon, a silicide material, such as ErSi1.7, PtSi, CoSi2 and NiSi, is formed. The formed silicide material has a characteristic of providing very high thermal stability.

The semiconductor material constituting the N-leg 107 and the P-leg 109 is easily reacted to the metal material by the heat treatment, so that the barrier material 111 in a form of the metal-semiconductor compound may be easily formed.

In the meantime, a process of fabricating the thermoelectric element according to the present disclosure will be schematically described. First, a semiconductor substrate 10 is formed on a silicon substrate 30 and an insulating layer 20, and the forms of the common electrode 101, the first and second electrodes 103 and 105, and the N-leg 107 and the P-leg 109 are defined through a semiconductor lithography process. Then, respective regions are formed through an etching process. Then, the N-leg 107 and the P-leg 109 are configured to sufficiently include electrons and holes, respectively, through an appropriate method, such as an ion implantation method. Next, a process of removing a photo resist only in a region, on which the metal is to be deposited, is performed through an additional lithography process, and a lift-off process of depositing the metal and removing the photo resist is performed. Depending on the necessity, a method of depositing the insulating layer, removing the insulating layer only in a region on which the metal-semiconductor compound is to be formed, and depositing the metal may be replaced with the lift-off process. Then, the metal-semiconductor compound is formed on only a desired region through the heat treatment and a process of removing a non-reacted metal, thereby implementing the thermoelectric element having the structure illustrated in FIG. 1.

Here, the semiconductor substrate 10, on which the common electrode 101, the first and second electrodes 103 and 105, the N-leg 107 and the P-leg 109 are formed, is formed of at least one of silicon (Si), germanium (Ge), silicon germanium (SiGe) and graphene. Further, in order to improve the thermoelectric property, a thickness of the semiconductor substrate 10 needs to be 100 nm or less.

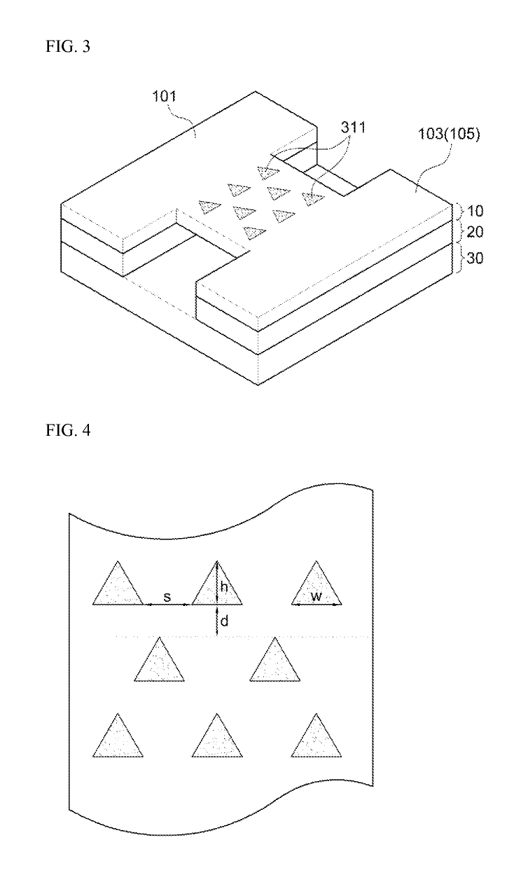

FIGS. 2, 3 and 4 are diagrams illustrating a form of a barrier material according to another exemplary embodiment of the present disclosure.

The barrier material within the thermoelectric element according to the present disclosure may have a band shape 111 vertically crossing the legs 107 and 109 as illustrated in FIG. 1, and may be formed in repeated figures 211 and 311 as illustrated in FIGS. 2 and 3.

In a case where the barrier material has the form of the repeated figures 311 using a triangle as illustrated in FIG. 3, when a distance between the horizontally arranged triangles is s, a length of a lower base of the triangle is w, a height of the triangle is h, and a vertical distance between the triangles is d as illustrated in FIG. 4, all of s, w, h and d are required to be sufficiently smaller than the wavelength of the phonon and sufficiently larger than the Fermi wavelength of the electron or the hole. In a case of general silicon, it is known that the wavelength of the phonon at the ordinary temperature is several hundreds of nm, and the Fermi wave of the electron or the hole is approximately 5 nm when the doping concentration is 10¹⁹ cm⁻³. Accordingly, appropriate sizes of s, w, h and d are in range of 10 to 300 nm.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A thermoelectric element comprising:
a common electrode configured to absorb heat;
a first electrode and a second electrode formed on an identical plane to a plane of the common electrode and configured to emit heat;
an N-leg connected between the common electrode and the first electrode and configured to supply electrons; and
a P-leg connected between the common electrode and the second electrode and configured to supply holes,
wherein a barrier material for suppressing thermal conduction between the common electrode and the first and second electrodes is formed in the N-leg and the P-leg.

2. The thermoelectric element of claim 1, wherein the barrier material has electric conductivity equal to or larger than a semiconductor material constituting the N-leg and the P-leg and thermal conductivity smaller than the semiconductor material.

3. The thermoelectric element of claim 2, wherein the barrier material is ohmic-contacted to the semiconductor material.

4. The thermoelectric element of claim 1, wherein the barrier material is formed of a metal-semiconductor compound including at least one of erbium (Er), europium (Eu), samarium (Sm), magnesium (Mg), platinum (Pt), ytterbium (Yb), nickel (Ni), cobalt (Co) and titanium (Ti) for preventing propagation of phonon.

5. The thermoelectric element of claim 1, wherein the barrier material has a form of a band vertically crossing the N-leg or the P-leg or a form of multiple repeated figures.

6. The thermoelectric element of claim 5, wherein when the barrier material is formed in the form of the multiple repeated figures, a distance among the multiple repeated figures is smaller than a wavelength of the phonon and is larger than a Fermi wavelength of the electron or the hole.

7. The thermoelectric element of claim 1, wherein the common electrode, the first and second electrodes, the N-leg and the P-leg are formed by using a substrate including at least one of silicon (Si), germanium (Ge), silicon germanium (SiGe) and graphene.

8. The thermoelectric element of claim 7, wherein the substrate on which the common electrode, the first and second electrodes, the N-leg and the P-leg are formed has a thickness of 100 nm or less.
